(19) United States
(12) Patent Application Publication
(10) Pub. No.: US 2026/0282770 A1
(43) Pub. Date: Sep. 17, 2026

(54) Microwave Single-Photon Detection Using a Hybrid Spin-Optomechanical Quantum Interface

(71) Applicant: Massachusetts Institute of Technology, Cambridge, MA (US)

(72) Inventors: Pratyush Anand, Medford, MA (US); Ethan G. Arnault, Stoneham, MA (US); Dirk Robert ENGLUND, Brookline, MA (US)

(21) Appl. No.: 19/027,405

(22) Filed: Jan. 17, 2025

Related U.S. Application Data
(60) Provisional application No. 63/622,040, filed on Jan. 17, 2024.

(51) Int. Cl. H10N 99/00; G01R 29/08; H10N 30/20

(52) U.S. Cl. CPC H10N 99/05; G01R 29/0885; H10N 30/20

(57) ABSTRACT

Semiconductor single-optical-photon detectors cannot be readily adapted for detecting microwave photons because microwave photons carry far less energy than optical photons. A hybrid spin-optomechanical interface can detect single microwave photons where the microwave photons are coupled to a phononic cavity via piezoelectric actuation. This phononic cavity also acts as a photonic cavity with either a single Silicon-Vacancy (SiV) center embedded in diamond or an ensemble of SiV centers, bridging optical single-photon detection protocols into the microwave domain. The detection process can be modeled as a communication channel whose capacity is quantified by the mutual information I(A; B) between the true photon occupancy (A) and the detector outcome (B). Depending on experimentally achievable parameters, simulations predict I(A; B) in the range 0.57 ln(2) to 0.67 ln(2), corresponding to true-positive (detection) probabilities above 90% and false-positive (dark count) probabilities below 10% per detection interval.

### CROSS-REFERENCE TO RELATED APPLICATION(S)

This application claims the priority benefit, under 35 U.S.C. 119(e), of U.S. Application No. 63/622,040, filed on Jan. 17, 2024, which is incorporated herein by reference in its entirety for all purposes.

### GOVERNMENT SUPPORT

This invention was made with government support under FA9550-20-1-0105 awarded by the Air Force Office of Scientific Research. The government has certain rights in the invention.

### BACKGROUND

The advancement of various quantum technologies has enabled quantum optics experiments in the single-photon regime. This requires efficient single-photon detection schemes in both the optical and microwave domains. Single-photon detection is also useful for quantum information processing and quantum communication. There are multiple platforms for single-photon detection in the optical domain. In the microwave domain, however, background thermal noise is a much larger fraction of the smaller microwave energy quanta, which makes detecting single microwave photons challenging. There have been recent developments in nearly quantum-limited amplification and homodyne measurement to extract microwave photon statistics, but efficient single-microwave-photon detection remains a puzzle.

The current state of the art for microwave photon detection comprises circuit-QED-based detectors, opto-electromechanical detectors, and quantum dot-based detectors with an efficiency in the range of about 0.5-0.7 and a dark count rate α of about 10⁴-10⁵ s⁻¹. There are also proposals for destructive readout schemes based on current-biased Josephson junctions. Non-destructive microwave photon detection with a fidelity of around 0.9 has been performed using cascaded transmon qubits coupled to a transmission line resonator. Recently, a flux qubit dispersively coupled to a coplanar waveguide (CPW) with a detection efficiency of 0.66 was realized. This system is an artificial Λ-type system using a flux qubit and a λ/2 resonator. However, circuit-QED-based detection strategies still suffer from low qubit coherence times, short-range connectivity, low qubit number, and low readout fidelities.

### SUMMARY

There have been efforts to mitigate these issues using solid-state defect platforms with coherence times approaching tends of milliseconds. For color centers (CCs), direct microwave single-photon-spin coupling is poor, so simply placing a CC in the vicinity of a microwave cavity does not lead to a strong coupling at the single-photon level. To enhance this coupling, intermediate systems can be used to transduce the microwave mode to a phononic mode. Specifically, a nitrogen vacancy (NV) center in a diamond waveguide can be electromechanically coupled to a CPW cavity in the presence of a micromagnet. Here, the detection is based on an optical cavity readout and the microwave single-photon-spin coupling is mediated via mechanical dark polaritons. This leads to a much higher coupling between spin and microwave photon in the single-photon regime.

Our single-microwave-photon detection platforms are based on a hybrid spin-optomechanical interface containing a silicon vacancy (SiV⁻) or another type of CC coupled to a microwave resonator via a piezoelectric transducer. Since the energy splitting of a Group IV CC depends on local strain, the phonon from the microwave resonator can be coupled directly with the SiV spin via the piezoelectric transducer. This platform can achieve quantum state transfer with fidelity exceeding 99% at a microsecond-scale bandwidth. This allows efficient transduction from a microwave photon to microwave phonons in the phononic cavity. The embedded SiV⁻ center allows for AC strain modulation, which couples spin and phonon degrees of freedom without a micromagnet. This system also allows simultaneous integration into a nanophotonic waveguide due to the electric field sensitivity of the Group IV CC. The spin of the Group IV CC can be read with single-shot optical readout at a fidelity that exceeds 99.9%. All these conditions provide good motivation to utilize our platforms for a single-microwave-photon detection.

Our detectors can detect microwave photons as follows. The microwave photon is coupled into a microwave cavity, e.g., using an antenna coupled to the microwave cavity. A piezoelectric transducer transduces the microwave photon into a microwave phonon, which is coupled into a phononic cavity (e.g., an optomechanical cavity, such as diamond patterned with holes and doped with a color center, that supports both phononic and optical modes). This coupling can be controlled by applying a current pulse to the piezoelectric transducer. A color center absorbs the microwave phonon. This causes an electron spin of the color center to change state. Reading out the state of the electron spin provides an indication of a presence or absence of the microwave photon in the microwave cavity. For example, the read out can be a single-shot readout performed by illuminating the color center with an optical pulse from a laser and detecting light emitted by the color center in response to the optical pulse with a photodetector. In cases where the color center is in an ensemble of color centers, reading out the state of the electron spin comprises performing a dispersive readout of states of the electron spins of ensemble of color centers, e.g., by making a homodyne measurement of microwave radiation from a microwave source reflected and/or transmitted by the phononic cavity. With this technology, the microwave photon's presence can be detected with a detection efficiency of 0.91-0.94 with a mutual information of 0.57 ln(2)-0.67 ln(2).

Alternatively, a single microwave photon can be detected by initializing a spin state of a color center coupled to a phononic cavity, mapping the single microwave photon to the spin state of the color center via the phononic cavity, and reading out the spin state of the color center. Mapping the single microwave photon to the spin state of the color center may include quantum state transduction, adiabatic mapping, or ensemble mapping. Likewise, reading out the spin state of the color center may include a single-shot readout of the spin state of the color center or dispersive readout of spin states of an ensemble of color centers comprising the color center.

All combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. The terminology explicitly employed herein that also may appear in any disclosure incorporated by reference should be accorded a meaning most consistent with the concepts disclosed herein.

### BRIEF DESCRIPTIONS OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar components).

FIG. 1A shows a schematic outline of an inventive hybrid spin-optomechanical single-microwave-photon detector.

FIG. 1B shows an inventive hybrid spin-optomechanical single-microwave-photon detector with a microwave (MW) cavity resonant with the microwave photon.

FIG. 1C shows an inventive hybrid spin-optomechanical single-microwave-photon detector suitable for detecting a traveling microwave photon with a wave packet of known shape and arrival time.

FIG. 1D shows an inventive hybrid spin-optomechanical single-microwave-photon detector suitable for detecting traveling microwave photons whose wave packets have unknown shapes and/or arrival times.

FIG. 2A illustrates a detection protocol for the single-microwave-photon detector shown in FIG. 1B.

FIG. 2B illustrates a detection protocol for the single-microwave-photon detector shown in FIG. 1C.

FIG. 2C illustrates a detection protocol for the single-microwave-photon detector shown in FIG. 1D.

FIG. 3A illustrates adiabatic mapping of a single microwave photon to a CC spin, e.g., as in the single-microwave-photon detector of FIG. 1C.

FIG. 3B illustrates mapping of a single microwave photon to an ensemble of CC spins, e.g., as in the single-microwave-photon detector of FIG. 1D.

FIG. 3C illustrates repetition of the adiabatic mapping of FIG. 3A for detecting a stream of single microwave photons.

FIG. 4A illustrates cavity-enhanced, single-shot readout of the spin of a silicon vacancy (SiV⁻).

FIG. 4B shows the energy level structure of the SiV⁻ of FIG. 4A with laser probing of the outer transitions, with dashed lines representing spin-conserving transitions and solid lines representing spin-flipping transitions.

FIG. 4C shows a confusion matrix representation of the readout scheme of FIG. 4A (TP: True Positive, TN: True Negative, FP: False Positive, FN: False Negative).

FIG. 4D is a plot of the success probability of single-shot readout as a function of probe laser pulse duration T and cooperativity C.

FIG. 4E is a plot of the variation of the success probability Pₛ (upper points) and Shannon's mutual information I(X; Y) (lower points) with respect to the threshold k.

FIG. 4F is a plot of the variation of TP, TN, FP, and FN with respect to the threshold k.

FIG. 5 shows an effective four-level diagram of a CC ensemble in the dispersive regime.

FIG. 6A is a plot of normalized amplitude versus time for pulse sequences used to transfer the state of a microwave cavity to an electron spin in an inventive hybrid spin-optomechanical single-microwave-photon detector.

FIG. 6B is a plot of transduction fidelity for the state transfer of FIG. 6A as a function of inter-pulse time-delay.

FIG. 6C is a close-up of the plot in FIG. 6B.

FIG. 6D is a plot of time-dependent microwave, phonon, and electron spin populations during the state transfer of FIG. 6A.

FIG. 6E is a plot of the variation of fidelity with the drive gₚₑ and γₑ.

FIG. 6F is a plot of the variation of infidelity with the drive gₚₑ and γₑ.

FIG. 7A is a plot of the normalized transfer fidelity ν, optimum drive g_{pe,n}, and incoming weak coherent pulse (n=0.01) versus time for the adiabatic mapping of an incoming microwave photon wave packet to an electron spin.

FIG. 7B is a plot of the variation in normalized transfer fidelity ν and efficiency η with the mean photon number n.

FIG. 7C is a plot of the variation in normalized transfer fidelity ν with t_{shift}. The horizontal dashed line denotes the threshold.

FIG. 7D is a plot of the cutoff ν_{cutoff} versus time window duration T_{window}.

FIG. 7E is a plot of the temporal profile with respect to the drive gₚₑ for points A, B, and C in FIG. 7C.

FIG. 8A is a plot of normalized temporal profiles of transfer fidelities, optimum drive, and an incoming weak coherent pulse (n=0.01) for mapping of an incoming microwave photon wave packet to a spin ensemble.

FIG. 8B is a plot of the dark-state fidelity versus gₘₚ and gₑₙₛ.

FIG. 8C is a plot of the dark-state fidelity versus gₘₚ and

$${T}_{2}^{*} .$$

FIG. 8D is a plot of the dark-state fidelity versus gₑₙₛ and

$${T}_{2}^{*} .$$

FIG. 9A is a plot of the success probability Pₛ and Shannon's mutual information I(X; Y) versus laser readout time T for single-shot readout of electron spin.

FIG. 9B is a plot of the success probability Pₛ and Shannon's mutual information I(X; Y) versus collection efficiency η for single-shot readout of electron spin.

FIG. 9C is a plot of the success probability Pₛ and Shannon's mutual information I(X; Y) versus detuning Δ (as illustrated in FIG. 4B) for single-shot readout of electron spin.

FIG. 9D is a histogram of probability versus counts for two electron spin states |↑ [symbol] and |↑ [symbol] ; the dotted line shows the thresholding.

FIG. 9E is a plot of the variation of dispersive readout fidelity [symbol] with optical drive strength Ωₒₚₜ for dispersive electron state readout.

FIG. 9F is a plot of the shift in resonance frequency of the phononic resonator depending on the microwave photon state for dispersive electron state readout.

FIG. 10 is a table summarizing simulations for the single-microwave-photon detectors shown in FIGS. 1B-1D.

### DETAILED DESCRIPTION

Using mechanics to mediate interactions between color centers and itinerant microwave photons enables high-efficiency, single-microwave-photon detection. Single-microwave-photon detectors can be used for a variety of specialized applications, including: (1) determining the presence or absence of a photon in a microwave cavity, and (2) determining the presence of an incident traveling-wave photon when the pulse shape and time of arrival of the photon are known. These single-microwave-photon detectors can operate with detection efficiencies in the range of 0.91-0.94 with mutual information of 0.57 ln(2)-0.67 ln(2). These efficiencies are larger than those of the currently available alternatives.

### 1 SINGLE-MICROWAVE-PHOTON DETECTOR ARCHITECTURES

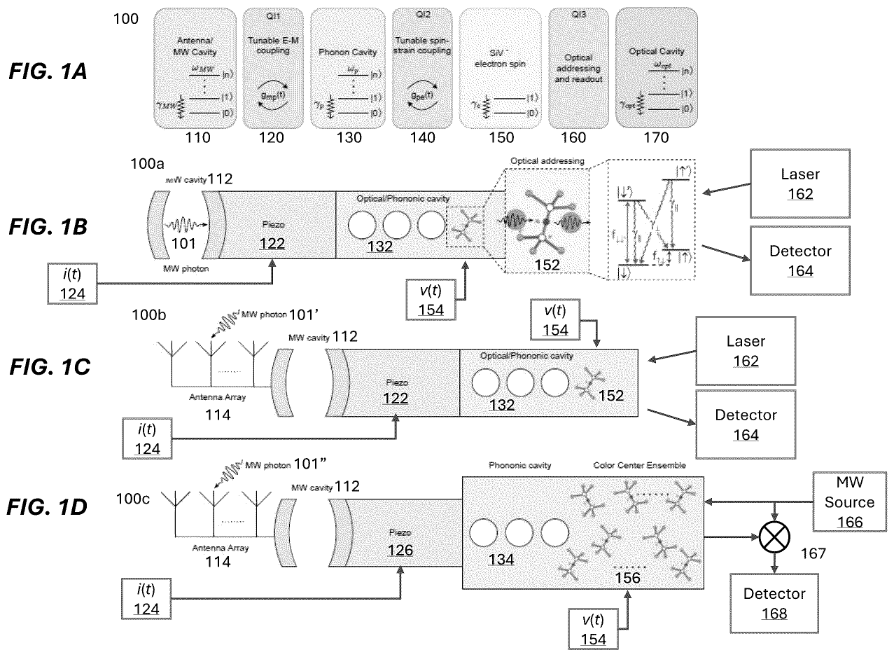

FIG. 1A shows a schematic of an inventive hybrid spin-optomechanical single-microwave-photon detector 100. The single-microwave-photon detector 100 includes a microwave (MW) cavity 110 connected via a first quantum interface (QI1) 120, e.g., in the form of a piezoelectrical transducer, to a phononic cavity 130, also called a phonon cavity. The first quantum interface 120 tunes or controls the coupling strength between the microwave cavity 110 and the phononic cavity 130. The phononic cavity 130 is coupled to the spin-orbit state(s) of one or more color centers (CCs) 150, such as a silicon vacancy (SiV⁻), tin vacancy (SnV), germanium vacancy (GeV), or other Group IV color, via a second quantum interface (QI2) 140, which can take the form of a magnetic field from a tunable magnetic field source (e.g., a current running through a loop) or a DC strain applied by a voltage source. An optical addressing and readout system 160 that includes laser and photodetector generates optical pulses that provide a third quantum interface (QI3) 170, together with an optical cavity that contains the CC(s) 150, for reading out the electron spin state(s) of the CC(s) 150.

The single-microwave-photon detector 100 detects single microwave photons as follows. First, a laser in the optical addressing and readout system 160 initializes the spin state of the SiV 150. During initialization, the laser is parked at the frequency f_{↑↑′} and thus, due to the nonzero cyclicity of optical transitions in the SiV⁻ 150, after a sufficient time the spin of the SiV⁻ 150 is initialized to the |↓ [symbol] state. The single-microwave-photon detector 100 is in thermal equilibrium with a dilution refrigerator (not shown) at roughly millikelvin temperatures, which corresponds to a thermal photon background of nₜₕ~0.1, so the number of thermal phonons and thermal photons in the phononic cavity 130 should be very low. A microwave photon is coupled into the microwave cavity 110, e.g., via an antenna, microwave transmission line, or coaxial cable. This microwave photon is transduced into a microwave phonon in the phononic cavity 130 via the first quantum interface 120. The second quantum interface 140 controls the coupling between the phononic cavity 130 and the SiV⁻ 150, which absorbs the microwave phonon, causing a change in its electron spin state. The electron spin state can be read out via the third quantum interface 170 to yield an indication of whether a microwave photon was present in the microwave cavity 110 (i.e., whether the single-microwave-photon detector detected a single microwave photon).

FIGS. 1B-1D show implementations of three different single-microwave-photon detectors 100a-100c. The single-microwave-photon detector 100a in FIG. 1B detects the presence of a microwave photon 101 in one mode of a microwave cavity 112, which is useful, for example, as part of a quantum processor. For example, the microwave photon 101 could be coupled into the microwave cavity 112 via a coaxial cable connecting the microwave cavity 112 to a quantum processor (not shown) that emits the microwave photon 101. The single-microwave-photon detector 100a detects the microwave photon 101 confined in the microwave cavity 112 using a single CC 152 embedded in an optomechanical cavity 152. A piezoelectric transducer 122 couples the microwave cavity 112 to the optomechanical cavity 132, which can be a diamond beam or cantilever doped with a SiV⁻ 152 or other color center and etched with a periodic array of nanoscale holes with sizes, shapes, and pitch(es) selected to produce resonances at both phononic (e.g., 3-7 GHz) and photonic (e.g., 420 THz) frequencies. The piezoelectric transducer 122 acts as the first quantum interface with a coupling strength gₘₚ(t) that can be controlled with a current source 134 coupled to the piezoelectric transducer 122.

The piezoelectric transducer 122 transduces the microwave photon 101 in the microwave cavity 110 into a microwave phonon in the optomechanical cavity 152, which also contains the SiV⁻ 152. Tuning the DC strain with a voltage source 154 or changing an external magnetic field with an external magnetic field source (not shown) applied to the SiV⁻ 152 tunes the coupling strength gₚₑ(t) between the optomechanical cavity 132 and the SiV⁻ 152 so that the SiV⁻ 152 absorbs the phonon. This causes the electron spin state of the SiV⁻ 152 to change. The laser 162 probes the SiV⁻ 152 again in a single-shot readout scheme that causes the SiV⁻ 152 to fluoresce, and a photodetector 164 senses the fluorescence, providing an indication that a single microwave photon was coupled into the microwave cavity 112.

The single-microwave-photon detector 100b in FIG. 1C includes all the components of the single-microwave-photon detector 100a in FIG. 1B plus an antenna 114 coupled to the microwave cavity 112. This antenna 114 receives an incident microwave photon 101′ and couples it into the microwave cavity 112. From there, the single-microwave-photon detector 100b operates in largely the same way as the single-microwave-photon detector 100a except for the second quantum interface, which adiabatically maps the microwave photon 101′ to the electron spin state as explained in greater detail below. This single-microwave-photon detector 100b is useful, for example, in a communication protocol, where the shape and arrival time of the microwave photon wave packet are known.

The third single-microwave-photon detector 100c, shown in FIG. 1D, acts as a microwave photon counter for traveling-wave microwave photons: it counts incident microwave photons regardless of their arrival times or the shapes of their wave packets. Like the second single-microwave-photon detector 100b, the third single-microwave-photon detector 100c includes an antenna 114 that is coupled to a microwave cavity 112, which in turn is coupled to a piezoelectric transducer 126 driven by a current source 124. This piezoelectric transducer 126 is also coupled to a phononic cavity 134 formed in a solid-state medium (e.g., a diamond beam or cantilever) patterned with nanoscale holes or other features. This solid-state medium is doped with an ensemble of color centers 156, such as SiV⁻, and is electromagnetically coupled to a microwave source 166 and a detector 168, such as an oscilloscope, analog-to-digital converter (ADC), or field-programmable gate array (FPGA), which are coupled to each other via a mixer 167.

Again, like the second single-microwave-photon detector 100b, the third single-microwave-photon detector 100c operates by receiving an incident microwave photon 101″ with the antenna 114, which couples that microwave photon 101″ into the microwave cavity 110. The current source 124 drives the piezoelectric transducer 126 to transduce the microwave photon 101″ into a microwave phonon in the phononic cavity 134. The SiV⁻ ensemble 156 absorbs the phonon, shifting the resonance of the phononic cavity 134. The microwave source 166, mixer 167, and detector 168 probe the phononic cavity's reflection or transmission in a homodyne measurement to provide an indication of the phononic cavity's resonance shift due to the presence of the microwave photon in the microwave cavity 110.

All three single-microwave-photon detectors 100a-100c work by mapping the quantum state of the incident microwave photon 101 onto the spin state of a CC 152 (or ensemble of CCs 156), and then measuring the spin state. The detection protocols for these single-microwave-photon detectors 100a-100c can be divided into two stages: mapping and readout.

### 2 DETECTION PROTOCOLS

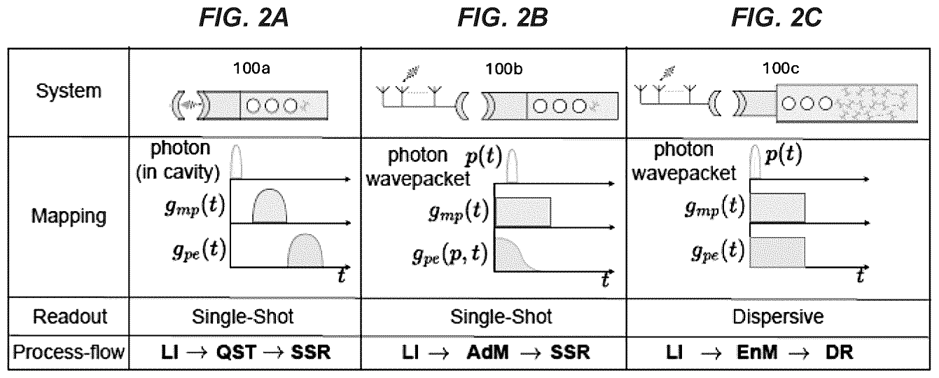

FIG. 2 illustrates detection protocols for the single-microwave-photon detectors 100a-100c shown in FIGS. 1B-1D. For the first single-microwave-photon detector 100a, shown in the left column of FIG. 2, the microwave cavity 112 is coupled to the optomechanical cavity 132 that contains the SiV⁻ 152. Again, this detector 100a works by detecting a single microwave photon in the microwave cavity using the mapping pulse sequence in the second (mapping) row of FIG. 2. After initialization of the color center's spin state, the voltage source 154 applies an electrostatic voltage to the diamond, straining the diamond and detuning the spin from the phonon modes, thereby effectively switching off the coupling gₚₑ(t) between the color center's spin and the strain in the piezoelectric transducer 122, and switching on the tunable electro-mechanical (E-M) coupling gₘₚ(t) provided by the first quantum interface (QI1). This tunable E-M coupling is mediated by the piezoelectric transducer 122 and acts as a gated detection window. The pulse gₘₚ(t) is pre-characterized such that it implements a swap operation between the microwave and phonon modes. Thus, if there is a microwave photon in the microwave cavity 112 before the detection window, it results in a single phonon state in the optomechanical cavity 132.

After the swap operation, the E-M coupling gₘₚ(t) is switched off and the spin-strain coupling gₚₑ(t) is switched on (QI2) again to perform the swap operation between the electron spin and the phonon mode. After this step, the spin-strain coupling gₚₑ(t) is switched off and the electron spin is read out in a single shot using the spin-photon interface (QI3). If a microwave photon 101 is in the microwave cavity 112, the electron spin will be in an excited state with some non-zero infidelity due to swap and readout. After the spin state has been read out, the single-microwave-photon detector 100a can be reset to detect more microwave photons by cooling the spin-phonon modes as done in the first step.

The single-microwave-photon detector 100b in FIG. 1C has the same structure and components as the first single-microwave-photon detector 100a except that the microwave cavity 112 is coupled to an antenna 114 that can couple with incident traveling-wave photons 101′. As seen in the middle column in FIG. 2, to map the incoming photon wave-packet to the electron spin, the E-M coupling gₘₚ(t) is on and acts as a detection window. During this detection window, a pulse drives the spin-strain coupling gₚₑ(t) in a way that is tailored to the shape and arrival time of a single-microwave-photon wave packet p(t). This increases or maximizes the transfer efficiency of the microwave photon to the electron spin. The efficiency of this mapping sequence depends on the temporal shape, coherence time, and arrival time of the photon wave packet. After mapping the microwave photon the spin state, the spin state can be read in a single shot as described above.

The single-microwave-photon detector 100c in FIG. 1D has the same structure and components of the single-microwave-photon detector 100b in FIG. 1C except (i) the single CC 152 is replaced with a CC ensemble 156, also called a spin ensemble, and (ii) the optomechanical cavity 132 is replaced with a phononic cavity 134. This single-microwave-photon detector 100c maps the quantum state of an arbitrary microwave photon 101″ onto the collective excitation of the spin-ensemble 134. The E-M coupling gₘₚ(t) and spin-strain coupling gₚₑ(t) are on as shown in the middle column of FIG. 2. Together, they act as a detection window and do not need to be tailored to the arrival times or wave packets of incident microwave photons. An incoming microwave photon, upon interacting with the antenna-cavity system 112, 114, begins to be transferred onto the bright excitation mode of the spin ensemble 156 via reversible (Hamiltonian) piezo-electric coupling to the phonons and from the microwave photon 101″ via strain to the spins. Due to the inhomogeneity of the spin ensemble 156, the bright mode dephases on the timescale of

$${T}_{2}^{*} .$$

This irreversibly transfers the bright mode, and thus the incident microwave photon 101″, into the dark modes of the spin ensemble where it remains until lost on the timescale of T₂. The irreversible dephasing allows the chain of reversible couplings to act as a transmission line down which the microwave photon 101″ travels to the dark spin modes. After this mapping, the spin ensemble 156 is driven into the dispersive regime, with dispersive readout of the collective state of the spin ensemble 156 yielding information about the presence of a microwave photon in the microwave cavity 112.

### 2. 1 Mapping a Microwave Photon to a Spin-Excitation

The bottom row of FIG. 2 shows the process flow for the detection schemes for the three single-microwave-photon detectors 101a-101c in FIGS. 1B-1D. The protocol for each single-microwave-photon detector 101a-101c has three stages: laser initialization (LI) of the CC electron spin(s), transduction/mapping of the input microwave photon into a state of the spin(s), and readout of the spin state. For single-microwave-photon detectors 101a, 101b, and 101c, the process of mapping the quantum state of a MW photon to the spin(s) involves, respectively, quantum state transduction (QST), adiabatic mapping (AdM), and ensemble mapping (EnM). Readout for first and second single-microwave-photon detectors 101a and 101b is single-shot readout (SSR), whereas readout for the third single-microwave-photon detector 101c is dispersive readout (DR).

### 2.2 Quantum State Transduction

The Hamiltonian describing the quantum state transduction involving the microwave, phonon, and spin degrees of freedom is given by:

$${\hat{H}}_{m - e} = {ℏω}_{mw} {\hat{a}}^{†} \hat{a} + {ℏω}_{p} {\hat{b}}^{†} \hat{b} + {ℏω}_{e} {\hat{σ}}_{e}^{†} {\hat{σ}}_{e} + ℏ {g}_{mp} ( t ) ( {\hat{a}}^{†} \hat{b} + \hat{a} {\hat{b}}^{†} ) + ℏ {g}_{pe} ( t ) ( {\hat{σ}}_{e}^{†} \hat{b} + {\hat{σ}}_{e} {\hat{b}}^{†} ) \qquad ( 1 )$$

Here â (â^{†}) is the microwave cavity annihilation (creation) operator, \hat{b}(\hat{b}^{†}) is the phononic cavity annihilation (creation) operator, and

$${\hat{σ}}_{e} ( {\hat{σ}}_{e}^{†} )$$

is the electron spin lowering (raising) operator. The frequencies ω_{mw}, ωₚ, and ωₑ correspond to the microwave, phonon, and electron-spin qubits, respectively. To incorporate losses into the system, we use the Lindblad equation of motion for the density matrix \hat{ρ}, and the Lindblad super-operators γ_{C}_{ᵢ} and [symbol] _{C}_{ᵢ}(φ:

$$\frac{d}{dt} \hat{ρ} = \frac{1}{i ℏ} [ {\hat{H}}_{m - e} , \hat{ρ} ] + {\sum }_{i} {γ}_{{c}_{i}} {ℒ}_{{c}_{i}} ( \hat{ρ} ) , \qquad ( 2 )$$

$$where$$

$${γ}_{{c}_{i}} {ℒ}_{{c}_{i}} ( \hat{ρ} ) = \frac{{γ}_{{c}_{i}}}{2} ( 2 {\hat{c}}_{i} \hat{ρ} {\hat{c}}_{i}^{†} - \{ {\hat{c}}_{i}^{†} {\hat{c}}_{i} , \hat{ρ} \} ) , \qquad ( 3 )$$

with

$${\hat{c}}_{i} ∈ \{ \hat{a} , \hat{b} , {\hat{σ}}_{e} {\hat{σ}}_{e}^{†} \}$$

and γ_{C}_{ᵢ}∈{γ_{mw}, γₚ, γₑ}, which represents the decay (or decoherence) rates of the respective modes. The Lindblad super-operators [symbol] ₐ(\hat{ρ}) and [symbol] _{b}(\hat{ρ}) describe the T₁ processes of microwave cavity decay and phonon decay, respectively. The super-operator

$${ℒ}_{{\hat{σ}}_{e} {\hat{σ}}_{e}^{†}} ( \hat{ρ} )$$

describes the T₂ process of pure dephasing of the electron spin qubit.

As can be seen in the left column of FIG. 2, the state-transfer protocol is based on two swap operations mediated by pulses gₘₚ(t) and gₚₑ(t). To avoid high-frequency components, we assume that the couplings have a smooth dependence on time given by

$${g}_{mp} ( t ) = {g}_{mp} sech ( 2 {g}_{mp} ( t - {τ}_{mp} ) ) \\ {g}_{pe} ( t ) = {g}_{pe} sech ( 2 {g}_{pe} ( t - {τ}_{pe} ) ) , \qquad ( 4 ) , ( 5 )$$

where gₘₚ, gₚₑ are time-independent amplitudes and τₘₚ, τₚₑ are time delays for the respective pulses. The time delay between pulses, Δτₘₚₑ=τₚₑ−τₘₚ, can be further adjusted for a given value of the parameters [γ_{mw}, γₚ, γₑ, gₘₚ, gₚₑ] in order to optimize the state-transfer fidelity [symbol] defined as:

$$ℱ = \vert Tr [ \sqrt{\sqrt{{\hat{ρ}}_{i}} {\hat{ρ}}_{f} \sqrt{{\hat{ρ}}_{i}}} ] \vert , \qquad ( 6 )$$

where \hat{ρ}ᵢ and \hat{ρ}_{f} are, respectively, the density matrices corresponding to the initial state of the microwave cavity and the final state of electron spin.

### 2.3 Adiabatic Mapping

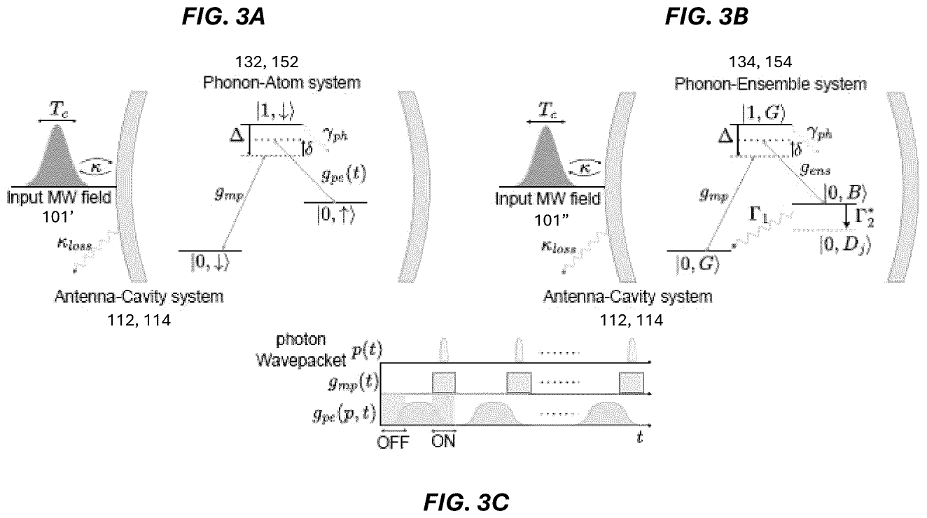

FIG. 3A illustrates the process of adiabatically mapping the traveling microwave photon 101′ to the excited state of the atomic spin in the single-microwave-photon detector 100b of FIG. 1C. In particular, FIG. 3A depicts the joint basis of the phonon mode and the spin qubit. The state in which there are n photons and the spin is in the excited (ground) state is denoted by |n, ↑ [symbol] (|n, ↓ [symbol] ).

In the adiabatic mapping process, an incoming microwave photon causes a change to the state of the CC spin. The transition |0, ↓ [symbol] ↔|1, ↓ [symbol] is coupled to the antenna-microwave cavity at a rate gₘₚ, thereby swapping the microwave and phonon states. Simultaneously, the time-dependent drive gₚₑ(t) couples the 1-Fock manifold |1, ↓ [symbol] ↔|0, ↓ [symbol] .

Put differently, the Λ-type transition shown in FIG. 3A makes it possible to perform an effective Raman transition (|0, ↓ [symbol] ↔|1, ↑ [symbol] ) in the presence of two drives, gₘₚ and gₚₑ. The Hamiltonian describing the coherent process is given by Ĥ(t)=Ĥ_{fields}+Ĥ₁(t), where

$${\hat{H}}_{fields} = \sqrt{κ} {ℰ}_{i n} ( t ) ( \hat{a} + {\hat{a}}^{†} ) \qquad ( 7 )$$

and Ĥ₁(t) is given below. The parameter K in the equation above is the cavity decay due to coupling of the antenna with the continuum of electromagnetic modes (the incoming photons), whereas the cavity loss to other modes is represented by κₗₒₛₛ. The operators â (â^{†}) correspond to the annihilation (creation) of the cavity mode. For simplicity, we assume that the incoming wave packet is a weak coherent pulse with temporal shape εᵢₙ(t) and mean photon number n. (The equations of motion for a single-photon wave-packet input to a cavity are identical to those for a coherent pulse, in which the wave-packet of the former maps to the amplitude profile of the latter.) While we assume the input profile to be a hyperbolic secant, the formalism is independent of the exact nature of the profile. The input profile is thus:

$${ℰ}_{i n} ( t ) = \frac{\sqrt{n}}{\sqrt{T}} sech ( \frac{2 t}{T} ) , \qquad ( 8 )$$

where the coherence time T_{c} of the microwave wave packet given by T_{c}=πT/4\sqrt{3}. The input profile satisfies the following relation:

$${\int }_{- ∞}^{+ ∞} {\vert {ℰ}_{i n} ( t ) \vert}^{2} dt = n \qquad ( 9 )$$

The interaction Hamiltonian in the rotating wave approximation is given by,

$${\hat{H}}_{1} ( t ) = δ \vert 0 , ↑ 〉 〈 0 , ↑ \vert - Δ \vert 1 , ↓ 〉 〈 1 , ↓ \vert + {g}_{m p} ( {\hat{a}}^{†} \vert 0 , ↓ 〉 〈 1 , ↓ \vert + \hat{a} \vert 1 , ↓ 〉 〈 0 , ↓ \vert + {g}_{pe} ( t ) \vert 1 , ↓ 〉 〈 0 , ↑ \vert + {g}_{pe}^{*} ( t ) \vert 0 , ↑ 〉 〈 1 , ↓ \vert , \qquad ( 10 )$$

where Δ=ω_{c}−ωₚₕ is the detuning between the antenna-cavity frequency ω_{c} and phonon-cavity frequency ωₚₕ, and δ=ωₑ+ωₒ−ω_{c} is the detuning between the spin frequency ωₑ and the antenna-cavity frequency ω_{c}, evaluated using the central frequency ωₒ of the drive gₚₑ(t). The incoherent evolution is simulated using Eq. (2), where the modified collapse parameters are cᵢ∈{â, \hat{b}, (|0, ↑ [symbol] 0, ↑|−|0, ↓ [symbol] 0, ↓|)} and γ_{C}_{ᵢ}∈{κ+κₗₒₛₛ, γₚ, γₑ}. The initial state of the system is

$${{\vert {ψ}_{0} 〉 = \vert 0 〉}_{c} ⊗ \vert 0 〉}_{p h} ⊗ \vert ↓ 〉 \qquad ( 11 )$$

and the projection operator for the desired target state is

$${\hat{P}}_{T} = {𝟙}_{c} ⊗ {𝟙}_{p h} ⊗ \vert ↑ 〉 〈 ↑ \vert \qquad ( 12 )$$

Here 1_{c} and 1ₚₕ denote, respectively, the identity operators for the microwave and phonon modes.

The transfer efficiency to map the state is then defined as

$$η ( t ) = T r ( {\hat{P}}_{T} \hat{ρ} ( t ) ) . \qquad ( 13 )$$

The fidelity of transfer ν is defined as the ratio of the transfer efficiency and the number of photons impinging on the antenna-cavity system:

$$ν ( t ) = \frac{η ( t )}{{\int }_{{t}_{1}}^{t} {\vert {ℰ}_{i n} ( τ ) \vert}^{2} d τ} . \qquad ( 14 )$$

The time interval for mapping is [t₁, t₂], with t₁<t<t₂, and we assume that the incoming wave packet interacts with the antenna only in this time interval. Thus, at the completion of the mapping process the transfer fidelity is

$$ν ≡ ν ( {t}_{2} ) = η ( {t}_{2} ) / n . \qquad ( 15 )$$

Given our definition of the transfer efficiency, in the limit of a weak coherent pulse, n<<1, the transfer fidelity ν approaches the single-photon storage efficiency ηₛₚ. In the adiabatic regime (i.e., γT_{c}C>>1), the optimal drive that maximizes ν(t₂) is given by:

$${g}_{pe}^{opt} ( t ) = \frac{γ ( 1 + C ) + i Δ}{\sqrt{2 γ ( 1 + C )}} \frac{{ℰ}_{i n} ( t )}{\sqrt{{\int }_{{t}_{1}}^{t} {\vert {ℰ}_{i n} ( τ ) \vert}^{2} d τ}} \times exp ( - i \frac{Δ}{2 γ ( 1 + C )} ln {\int }_{{t}_{1}}^{t} {\vert {ℰ}_{i n} ( τ ) \vert}^{2} d τ ) , \qquad ( 16 )$$

where C is the effective cooperativity of the system,

$$C = \frac{{g}_{m p}^{2}}{{γ}_{p h} ( κ + {κ}_{loss} )} . \qquad ( 17 )$$

Numerical simulations of the adiabatic mapping are discussed below. This protocol can be repeated continuously to detect multiple incoming microwave wave packets as depicted in FIG. 3C. In FIG. 3C, the ON shaded area serves as the detection window. In the OFF shaded region, the drive gₚₑ is time-reversed from that in the ON region, and the coupling gₘₚ is turned off to prevent emission of the microwave photon back into the microwave cavity.

### 2.4 Absorption of the Microwave Photon by the Color Center Spin Ensemble

For detection of a single microwave photon, it is not necessary to retrieve the stored microwave photon. Thus, a single-microwave-photon detector with a color center spin ensemble can use a similar scheme for microwave photon storage with the constraint of efficient retrieval relaxed.

FIG. 3B shows a schematic of the ensemble mapping process. In the ensemble mapping process, an incoming microwave photon causes a change to the state of the ensemble of CC spins. The transition |0, G [symbol] ↔|1, G [symbol] is coupled to the antenna-microwave cavity at a rate gₘₚ, thereby swapping the microwave and phonon states. The effective phonon-spin ensemble coupling gₑₙₛ couples the 1-Fock manifold |1, G [symbol] ↔|0, B [symbol] . Due to the spin inhomogeneity, the bright state |0, B [symbol] dephases to one of the ensemble dark states |0, D [symbol] on the timescale of

$${T}_{2}^{*} .$$

This results in the irreversible absorption of the photon into a collective dark state of the ensemble.

One difference between the ensemble mapping process in FIG. 3B and the single-spin mapping process in FIG. 3A is that the ensemble dephasing process continually transforms the bright collective state of the ensemble to which the microwave photon is being mapped into the space of “dark” collective spin states that do not interact with the phonon mode. In this way the spin ensemble acts as a bath that irreversibly transfers the microwave photon into the dark collective states of the ensemble. This irreversible process allows the ensemble to absorb the microwave photon without having to tailor time-varying drives gₘₚ and gₚₑ. This occurs because the decay rate into the spin ensemble is impedance-matched to the decay rate of the microwave cavity to ensure that the microwave photon is absorbed by the microwave cavity (and in turn the ensemble) rather than being reflected.

The Hamiltonian for the coherent part of the process is given by Ĥ(t)=Ĥ_{fields}+Ĥₑₙₛ(t), where the description of the wave packet is the same as in Eqs. (7)-(9). The other part of the Hamiltonian is given by

$${\hat{H}}_{ens} = {ℏω}_{mw} {\hat{a}}^{†} \hat{a} + {ℏω}_{p h} {\hat{b}}^{†} \hat{b} + {\sum }_{j = 1}^{N} ℏ ( {ω}_{j} / 2 ) {\hat{σ}}_{z , j} + ℏ {g}_{m p} ( {\hat{a}}^{†} \hat{b} + \hat{a} {\hat{b}}^{†} ) + {\sum }_{j = 1}^{N} ℏ {g}_{j} ( {\hat{b}}^{†} {\hat{σ}}_{- , j} + \hat{b} {\hat{σ}}_{+ , j} ) . \qquad ( 18 )$$

Here â and \hat{b} are the MW and phononic cavity annihilation operators, \hat{σ}_{x,j}, with x=z, γ are the various spin operators for the j^{th} spin qubit, and ωⱼ and gⱼ are, respectively, the splitting frequency and the phonon coupling rate for the j^{th} spin qubit. In the limit in which the number of excitations in the spin ensemble is much smaller than the number of spins, N, the ensemble effectively behaves as a resonator. Therefore, the Pauli lowering operator (\hat{σ}_{-, j}) can be replaced by a Bosonic annihilation operator (ŝⱼ). In the interaction picture the Hamiltonian becomes

$${\hat{H}}_{ens} = {\sum }_{j = 1}^{N} ( {δ}_{j} \vert 0 〉 〈 0 \vert ⊗ {\hat{s}}_{j}^{†} {\hat{s}}_{j} - {Δ}_{j} \vert 1 〉 〈 1 \vert ⊗ {\hat{s}}_{j} {\hat{s}}_{j}^{†} ) + ℏ {g}_{m p} ( {\hat{a}}^{†} \hat{b} + \hat{a} {\hat{b}}^{†} ) + ℏ {g}_{ens} ( \vert 1 , G 〉 〈 0 , B \vert + \vert 0 , B 〉 〈 1 , G \vert 〉 . \qquad ( 19 )$$

In the collective excitation picture of the ensemble, |G [symbol] and |B [symbol] correspond to the collective ground state and first bright state, respectively, related by:

$$\vert B 〉 = {\hat{s}}_{ens}^{†} \vert G 〉 , \qquad ( 20 )$$

$${\hat{s}}_{ens} = {\sum }_{j = 1}^{N} {g}_{j} {\hat{s}}_{j} / {g}_{ens} , \qquad ( 21 )$$

$${g}_{ens} = \sqrt{{\sum }_{j = 1}^{N} {g}_{j}^{2}} = \sqrt{N} \sqrt{〈 {g}_{j}^{2} 〉} , \qquad ( 22 )$$

where

$$〈 {g}_{j}^{2} 〉$$

denotes the squared coupling of each of the spins averages over the ensemble. In the above equations ŝₑₙₛ and gₑₙₛ are the collective excitation operator and collective coupling of the ensemble, respectively, in which the latter is enhanced by \sqrt{N}. In the presence of inhomogeneous broadening, which is characterized by the width I′ of the distribution of spin resonance frequencies ρ(ωⱼ), the bright mode |B [symbol] is not an eigenstate and thus redistributes/decays to the N−1 excitation (dark) states |Dⱼ [symbol] on the timescale of

$${T}_{2}^{*} = {Γ}^{- 1}$$

(similar to free induction decay).

FIG. 3B shows an effective state-level diagram of the various transitions. This incoherent evolution is simulated using an equation similar to Eq. (2), where the collapse parameters are given by cᵢ∈{â, \hat{b}, (|0, D [symbol] 0, B|)} and γ_{C}_{ᵢ}∈{κ+κₗₒₛₛ, γₚₕ, Γ}. Since, the incoming photon state is mapped to state |D [symbol] , we define the following projection operator \hat{P}_{T} as

$${\hat{P}}_{T} = {𝟙}_{c} ⊗ {𝟙}_{p h} ⊗ \vert D 〉 〈 D \vert . \qquad ( 23 )$$

The definitions for transfer efficiency (η) and fidelity (ν) are the same as those given in Eqs. (11)-(15). After the state is mapped onto the dark state, it can be read out using the dispersive readout scheme discussed below.

2.5 Reading Out the Spin State with a Cavity-Enhanced Single-Shot Readout

After the two swap operations, the spin states of the individual color centers in the single-microwave-photon detectors 100a and 100b can be read out using cavity-enhanced, single-shot readout. Optical readout of solid-state qubits is typically based on resonance fluorescence, and the readout fidelity is limited by the branching ratio corresponding to the spin-flipping transitions. For silicon vacancies, the branching ratio depends on the alignment angle α of the static magnetic field with the SiV⁻ symmetry axis. In reference, for α<5°, a cyclicity of more than ~10⁵ was achieved. Further, despite a low photon collection efficiency, a laser readout time of 10 ms yields a single-shot readout fidelity of about 89%.

Since the duration of the laser readout determines the detection time of our protocol, a low laser readout time is preferable. Since a SiV⁻ is a Group-IV CC and is first-order insensitive to the electric field (unlike nitrogen-vacancy centers), the readout time can be reduced by several orders of magnitude and the photon collection efficiency can be increased to above 10% by integrating the SiV⁻ into a nanostructure, such as a beam or cantilever formed of diamond or another solid-state material and patterned with holes or a solid-state, photonic-crystal(-like) structure.

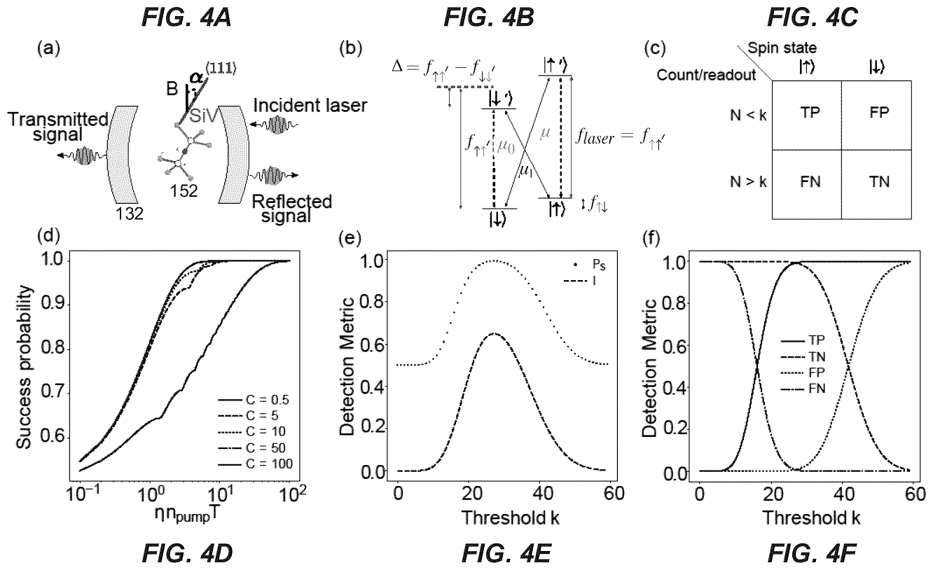

FIG. 4A shows readout architecture with a SiV⁻ in an optical cavity. FIG. 4B shows the λ-type energy structure corresponding to two of the C-transitions of the SiV⁻. The parameters μ₀ and μ₁ represent the transition dipole moments of the dipole-allowed spin-conserving and dipole-forbidden spin-flipping optical transitions, respectively. We assume that the SiV⁻ is in the strain regime for which μ₁<μ₀ so that we can neglect the laser-induced μ₁ transitions. For performing optical readout, the optical cavity is resonant with the f_{↑↑′} transition and is detuned from the ↓↓′ transition by Δ. In this operating regime, the atom-cavity coupling depends on the spin state, which also affects the reflection and transmission coefficients of the optical cavity. Hence, probing the transmission/reflection coefficient of the optical cavity is a non-destructive, single-shot readout of the spin state.

During readout, the transmittivity of the optical cavity is resonantly probed using a laser pulse of duration T, with an incident photon flux of nₚᵤₘₚ (units of number of photons per unit time). In the weak excitation regime (i.e., nₚᵤₘₚ<<1/τ, where τ is the modified lifetime of the |↑′ [symbol] state), the average numbers of transmitted photons when the spin is in each of its two states are given by

$${N}_{0} ( T ) = \frac{η {Tn}_{pump}}{{( 1 + C )}^{2}} , spin in state \vert ↑ 〉 \qquad ( 24 )$$

$${N}_{1} ( T ) = η {Tn}_{pump} , spin in state \vert ↓ 〉 \qquad ( 25 )$$

where η is the overall photon collection efficiency accounting for the coupling efficiency of the optics, imperfect spatial mode matching between the incident optical photon and the cavity, and the quantum efficiency of the photodetector. The atomic cooperativity of the optical cavity is defined by C=2g²/(κγ), where g is the coupling strength between the optical cavity and the μ₀ transition, κ is the decay rate of the optical cavity, and γ is the decay rate of the excited state.

The expressions for N₀₍₁₎ (T) in Eqs. (24) and (25) do not account for the possibility of a spin flip during the measurement process. To take this into account, we evolve the master equation for the system during the measurement process and calculate the average value of the photon emission rate when the initial state of the spin is either up or down. We then set N₀(T) and N₁ (T) equal to these average rates, respectively. This gives the expression

$${N}_{0 ( 1 )} ( T ) = η {\int }_{0}^{T} Tr [ κ {\hat{c}}^{†} \hat{c} {\hat{ρ}}_{0 ( 1 )} ( t ) ] dt , \qquad ( 26 )$$

where ĉ is the annihilation operator for the cavity mode, and \hat{ρ}₀(1)(t) is the density matrix of the spin-cavity system at time t, for the initial states |1 [symbol] and |4 [symbol] , respectively. We can solve numerically for \hat{ρ}(t) by using a Lindblad master equation, Eq. (2), using the following readout Hamiltonian in the reference frame with respect to the laser frequency ω:

$${H}_{ro} = ℏ ( {ω}_{c} - ω ) {c}^{†} c + ℏ ( {ω}_{a} - ω ) \vert {↑}^{′} 〉 〈 {↑}^{′} \vert + ℏ ( {ω}_{a} - Δ - ω ) \vert {↓}^{′} 〉 〈 {↓}^{′} \vert + i ℏ g ( c \vert {↑}^{′} 〉 〈 ↑ \vert - {c}^{†} \vert ↑ 〉 〈 {↑}^{′} \vert ) + i ℏ g ( c \vert {↓}^{′} 〉 〈 ↓ \vert - {c}^{†} \vert ↓ 〉 〈 {↓}^{′} \vert ) + ℏ \sqrt{κε} ( c + {c}^{†} ) . \qquad ( 27 )$$

To incorporate losses, we use Eq. (3) for the Lindblad super-operators with a new set of decay parameters

$${c}_{i}^{R O} ∈ \{ c , \vert ↑ 〉 〈 {↑}^{′} \vert , \vert ↓ 〉 〈 {↑}^{′} \vert , \vert ↑ 〉 〈 {↓}^{′} \vert , \vert ↓ 〉 〈 {↓}^{′} \vert , \vert {↑}^{′} 〉 〈 {↑}^{′} \vert , \vert {↓}^{′} 〉 〈 {↓}^{′} \vert \} , \qquad ( 28 )$$

$${γ}_{{c}_{i}}^{RO} ∈ \{ κ , {γ}_{0} , {γ}_{1} , {γ}_{2} , {γ}_{3} , 2 {γ}_{2} , 2 {γ}_{d} \} \qquad ( 29 )$$

Here γ₀ and γ₃ correspond to the spin-conserving decays, γ₁ and γ₂ correspond to the spin-flip decays, and γ_{d} corresponds to the pure dephasing rate for the states |↑′ [symbol] and |↓′ [symbol] . The incident field amplitude of the laser, ϵ, is chosen to be much smaller than g/\sqrt{κ}, so that we stay in the weak field linear regime.

To distinguish between measurement results for |↑ [symbol] and |↓ [symbol] , we choose a threshold number k, comparing the number of collected photons N_{c} with k. When N_{c}<k, we report the spin state to be |↑ [symbol] (presence of a microwave photon), whereas when N_{c}>k, we report the spin state to be |↓ [symbol] (absence of a microwave photon). There are multiple metrics that can be obtained based on the above classification scheme as seen in FIG. 4C.

Given two possibilities for the microwave photon (presence or absence) and two measurement results (reporting the presence or absence of the microwave photon) there are four potential outcomes: TP (True Positive, in which we correctly report the presence of the photon); TN (True Negative); FP (False Positive or “dark count”); and FN (False Negative). Assuming a Poissonian distribution of the collected photons, the expressions for the probabilities of these outcomes are:

$$TN = 1 - {\sum }_{j = 0}^{k} ( \frac{{[ {N}_{1} ( T ) ]}^{j} {e}^{- {N}_{1} ( T )}}{j !} ) ,$$

$$TP = {\sum }_{j = 0}^{k} ( \frac{{[ {N}_{0} ( T ) ]}^{j} {e}^{- {N}_{0} ( T )}}{j !} ) ,$$

$$FP = {\sum }_{j = 0}^{k} ( \frac{{[ {N}_{1} ( T ) ]}^{j} {e}^{- {N}_{1} ( T )}}{j !} ) ,$$

$$FN = 1 - {\sum }_{j = 0}^{k} ( \frac{{[ {N}_{0} ( T ) ]}^{j} {e}^{- {N}_{0} ( T )}}{j !} ) .$$

Based on these expressions, the following figure of merits can be deduced: the success probability Pₛ, Shannon's mutual information I(X; Y), and the intrinsic dark count rate, [symbol] . These are given by

$${P}_{s} ( k ) = q \cdot TP + p \cdot TN , \qquad ( 34 )$$

$$I ( X ; Y , k ) = p \cdot TN \cdot log ( \frac{T N}{p \cdot TN + q \cdot FN} ) + p \cdot FP \cdot log ( \frac{F P}{p \cdot FP + q \cdot TP} ) + q \cdot FN \cdot log ( \frac{F N}{p \cdot TN + q \cdot FN} ) + q \cdot TP \cdot log ( \frac{T P}{p \cdot FP + q \cdot TP} ) , \qquad ( 35 )$$

$$𝒟 = FP / {T}_{0} , \qquad ( 36 )$$

where q and p are the probabilities that the spin is in the states |↑ [symbol] and |↓ [symbol] , respectively; X and Y are the distributions for the spin-state and their predictions, respectively; and T₀ is the time for the complete protocol.

FIG. 4E shows that both the success probability Pₛ and Shannon's mutual information I(X; Y) depend on the threshold parameter k. Hence, for each set of parameters, an optimum value of k can be obtained which maximizes the success probability Pₛ or Shannon's mutual information I(X; Y). FIG. 4F shows that at an optimal value of k, TP and TN are high whereas FP and FN are low, as demanded by the detection protocol. Depending on the rarity of the detection event and sensitivity required, different figures of merit can be used. For example, for anomaly detection, Rényi information may be more sensitive than Shannon information due to its asymmetric form. Here, we use Pₛ and I(X; Y) as figures of merit of our protocol.

### 2.6 Dispersive Readout of a Spin Ensemble

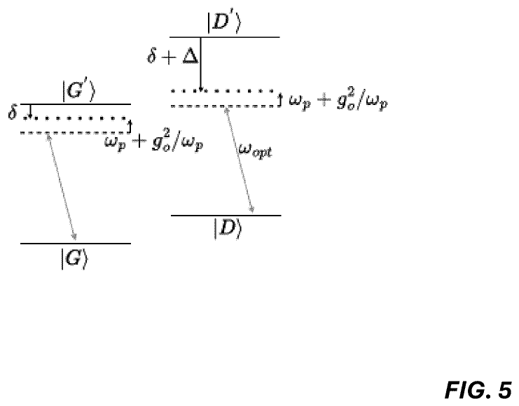

FIG. 5 shows the energy levels |G [symbol] and |G′ [symbol] with an optical drive of strength Ωₒₚₜ and frequency ωₒₚₜ. The optical drive is started after the ensemble mapping described above. The parameter gₒ describes the coupling between the state |G′ [symbol] and phononic cavity. The Hamiltonian of the detection system is given by:

$${\hat{H}}_{QND} = {ω}_{p} {\hat{b}}^{†} \hat{b} + {ω}_{{GG}^{′}} \vert {G}^{′} 〉 〈 {G}^{′} \vert + \frac{{Ω}_{opt}}{2} ( {e}^{i t {ω}_{opt}} \vert G 〉 〈 {G}^{′} \vert {e}^{- i t {ω}_{opt}} \vert {G}^{′} 〉 〈 G \vert ) + {g}_{o} ( \hat{b} + {\hat{b}}^{†} ) \vert {G}^{′} 〉 〈 {G}^{′} \vert . \qquad ( 37 )$$

where

$${ω}_{{GG}^{′}} = {ω}_{opt} + {ω}_{p} + {g}_{o}^{2} / {ω}_{p} + δ .$$

After applying the Schrieffer-Wolff transformation with respect to the unitary

$$U = exp [ \frac{{g}_{o}}{{ω}_{p}} ( {\hat{b}}^{†} - \hat{b} ) \vert {G}^{′} 〉 〈 {G}^{′} \vert ] \qquad ( 38 )$$

and a sequence of two rotating-wave approximations, first with respect to

$${\hat{H}}_{r 1} = {ω}_{p} {\hat{b}}^{†} \hat{b} + ( {ω}_{{GG}^{′}} - \frac{{g}_{o}^{2}}{{ω}_{p}} - δ ) \vert {G}^{′} 〉 〈 G \vert \qquad ( 39 )$$

and then with respect to Ĥᵣ₂=δ|G′ [symbol] G|, yields the following Hamiltonian:

$${\hat{H}}^{′} = \frac{{g}_{o} {Ω}_{opt}}{2 {ω}_{p}} ( {e}^{i δ t} {\hat{b}}^{†} \vert {G}^{′} 〉 〈 G \vert + {e}^{- i δ t} \hat{b} \vert G 〉 〈 {G}^{′} \vert ) . \qquad ( 40 )$$

Finally, in the dispersive regime the application of a perturbation expansion in which the interaction with the phonon mode perturbs the spin ensemble, the effective Hamiltonian becomes

$${\hat{H}}_{DR} = \frac{{g}_{o}^{2} {Ω}_{opt}^{2}}{4 {ω}_{p}^{2} δ} [ {\hat{b}}^{†} \hat{b} ( \vert {G}^{′} 〉 〈 {G}^{′} \vert - \vert G 〉 〈 G \vert ) + \vert G 〉 〈 G \vert ] . \qquad ( 41 )$$

There are three stages to dispersive readout of a spin ensemble. In the first stage, a coherent microwave drive is applied to the phononic cavity to prepare the cavity mode in a coherent state. The cavity photon number should be as large as possible but no larger than

$${n}_{crit} = \frac{4 {ω}_{p}^{2} {δ}^{2}}{{g}_{o}^{2} {Ω}_{opt}^{2}} \qquad ( 42 )$$

to maintain the validity of the perturbation expansion. The phononic cavity decay rate γₚₕ also determines its coupling to the drive. Fast readout uses a large value of γₚₕ, increasing the rate of phonon loss. In the second stage phonons, interact with the spin ensemble and the excitation in the spin ensemble produces a phase shift of the coherent state. The rate at which this phase shift is accumulated is given by the effective coupling rate

$$2 χ = \frac{{g}_{o}^{2} {Ω}_{opt}^{2}}{2 {ω}_{p}^{2} δ} . \qquad ( 43 )$$

In the third stage, heterodyne detection is used to measure the phase and amplitude of the output from the cavity.

### 3 NUMERICAL SIMULATIONS

We now present the results of simulating the operation of the three types of single-microwave-photon detector described above. As explained above, the protocols for each type of single-microwave-photon detector have two stages: mapping (employing one of the QST, AdM, or EnM protocols) and readout (either SSR or DR readout). We used two metrics, the success probability Pₛ and the mutual information I(X; Y), for evaluating the protocols.

### 3.1 Quantum State Transduction

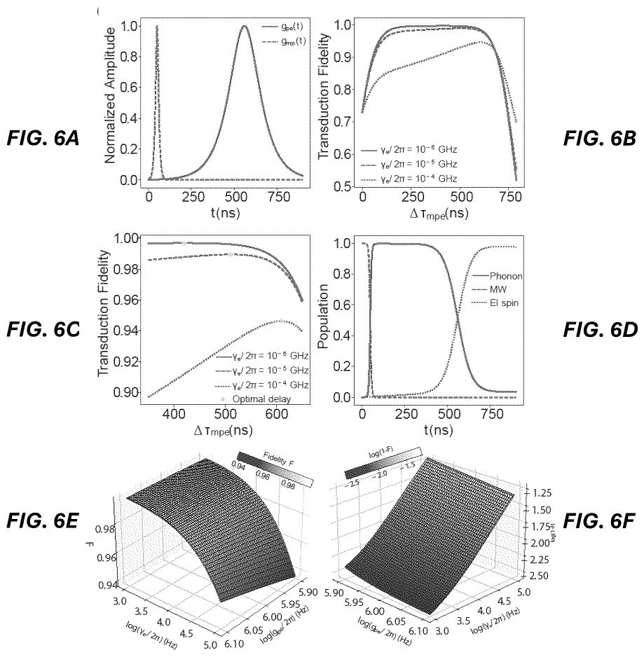

We simulated the master equation with the Hamiltonian described in Eq. (1) and collapse operators given in Eq. (3). FIGS. 6A-6F show the results of this simulation using the time-dependent pulse sequences for the microwave-phonon swap and the phonon-spin swap (FIG. 6A). As the time delay between the two pulses is varied, the transduction fidelity changes, as shown in FIGS. 6B and 6C. The point at which the maximum fidelity is obtained is marked by the star. As γₑ is reduced, the fidelity increases and the optimal time-delay decreases. FIG. 6D is a plot of the time-dependent population for the microwave, phonon, and electron spin modes using the optimal value of time-delay and γₑ/2π=10 kHz. FIGS. 6E and 6F show the variations in fidelity and infidelity, respectively, with variations in gₚₑ and γₑ over a realistic range. The time delay is adjusted to maximize [symbol] for each pair of parameters [gₚₑ, γₑ]. [symbol] varies in the range (0.937, 0.997) with a standard deviation of 0.015.

### 3.2 Adiabatic Mapping

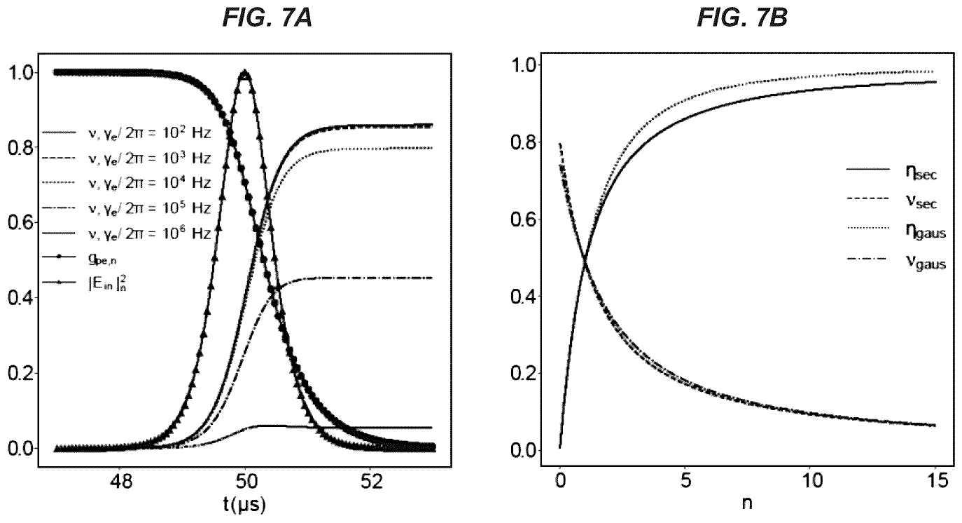

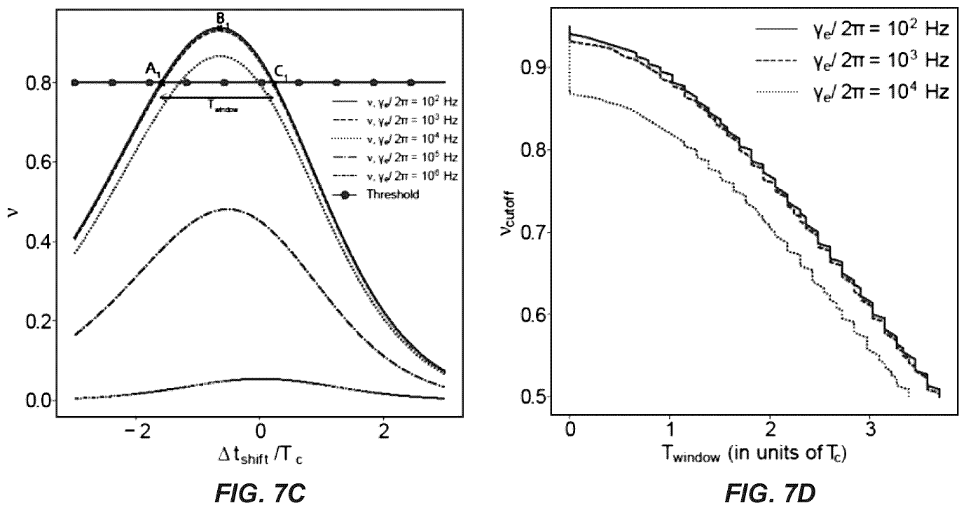

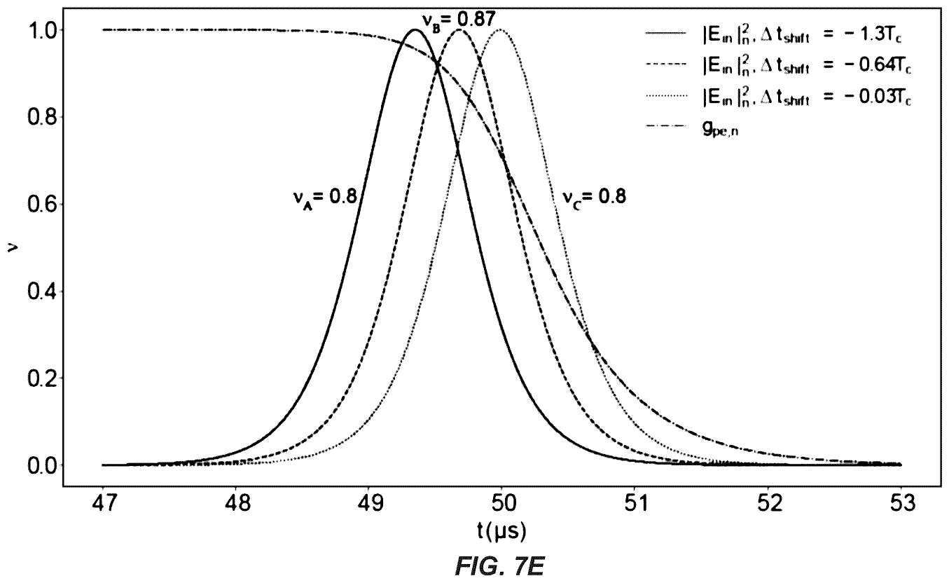

We simulated the master equation with Hamiltonian and optimal driving described in Eqs. (7)-(10) and (16). FIG. 7A shows the normalized time profile of the incoming weak coherent pulse (n=0.01), with the normalized optimum drive g_{pe,n} and the transfer fidelity ν, which saturates at 0.86. FIG. 7B shows the variation of the fidelity ν and efficiency η with the mean photon number n in the incoming wave packet. For low photon number, these figures of merit coincide for two different temporal shapes of the incoming wave packet (hyperbolic secant and Gaussian). Shifting the incoming wave packet by t_{shift} from the center of the drive leads to a variation in the fidelity, with a maximum of 0.939 achieved for point B, as seen in FIG. 7C. Fixing the cutoff fidelity ν_{cutoff} at 0.8 gives a range (A-C) with a detection window T_{window}. Changing ν_{cutoff} changes the detection window, implying that lowering the cutoff fidelity increases this window (FIG. 7D). FIG. 7E shows the temporal profile with respect to the drive gₚₑ for the three points (A, B, and C) shown in FIG. 7C, giving a window of about 1.82T_{c}.

### 3.3 Ensemble Mapping

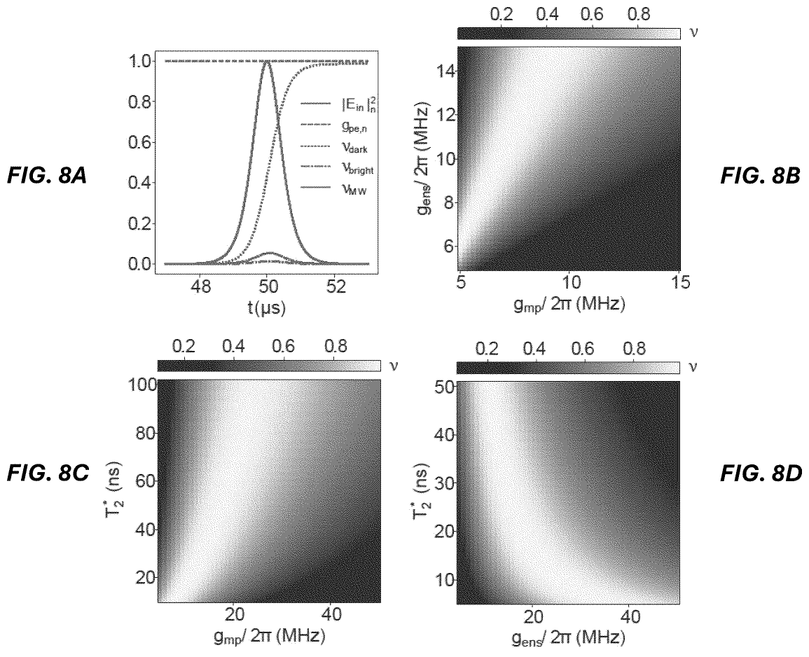

We simulate the master equation with the Hamiltonian given in Eq. (19). FIG. 8A shows the normalized time profile of the incoming weak coherent pulse (n=0.01), with the constant normalized drive g_{pe,n}, and the transfer fidelity ν_{dark}, which saturates at 0.986. FIGS. 8B, 8C, and 8D show the results of varying gₘₚ, gₑₙₛ, and

$${T}_{2}^{*} ,$$

respectively. FIGS. SB-8D can be used to find a suitable range of coupling strengths which maximize the transfer fidelity ν_{dark}.

### 3.4 Single-Shot Readout

FIG. 4D shows the success probability Pₛ (upper points) as a function of the laser readout time T and cooperativity C, based purely on the expressions for N₀(T) and N₁ (T) given in Eqs. (24) and (25). In this case P increases monotonically with T, but as discussed above this picture is incomplete as it does not include the possibility of spin-flips during the readout time. Simulating the master equation with the Hamiltonian in Eq. (27) and decay operators given in Eqs. (28) and (29) improves the simulation accuracy. This provides the average values of N₀₍₁₎ given that the spin is initially in the states |↑ [symbol] (|↓ [symbol] ), and subsequently the readout metrics in Eqs. (30)-(35).

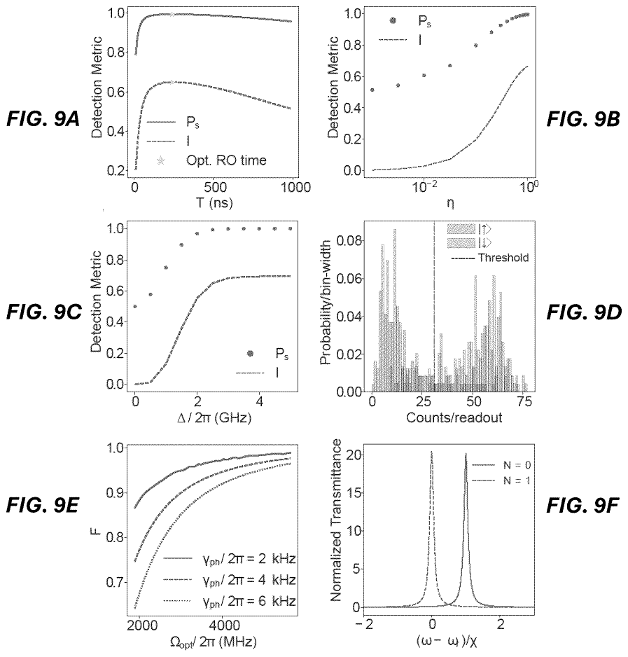

FIG. 9A shows the variation of Pₛ and I(X; Y) with the laser readout time. These initially increase and then start to decrease due to spin-flip transitions and other decay channels, with the stars marking the optimum value at T~240 ns. FIGS. 9B and 9C show Pₛ and I(X; Y) as functions of the efficiency η and the detuning Δ, respectively, for the optimum value of T, showing an asymptotic behavior for both. FIG. 9D shows the results of a quantum Monte-Carlo simulation with the same Hamiltonian at the optimal value of T and η=0.85. The dotted line in FIG. 9D shows the thresholding parameter, such that only an event falling to the left of the dotted line is classified as detection of a single microwave photon. The resulting overall success probability is about 0.972.

### 3.5 Dispersive Readout

Dispersive readout can be simulated with the Hamiltonian in Eq. (41). FIG. 9E shows the variation of the readout fidelity [symbol] with optical drive strength Ωₒₚₜ for dispersive readout. FIG. 9F shows the shift in the resonance frequency of the phononic resonator due to the presence of a microwave photon, which yields a fidelity of 0.924.

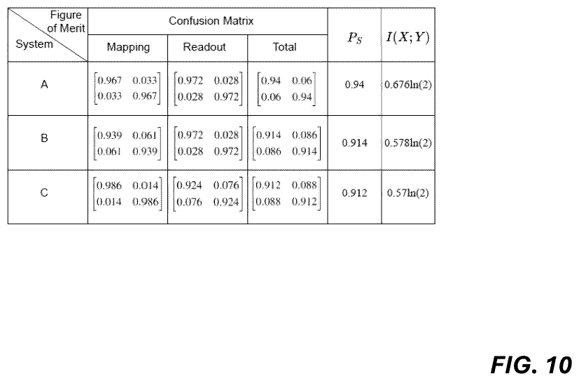

FIG. 10 shows confusion matrices for the mapping, readout, and overall (total) protocols as well as the success probabilities and Shannon's mutual information for the different types of single-microwave-photon detectors 100a-100c. The overall confusion matrix for each detector is the product of the confusion matrices for the mapping and readout steps. The simulations show maximum detection efficiencies of 0.94, 0.914, and 0.912 for the single-microwave-photon detectors 100a, 100b, and 100c, respectively.

### 4 CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the components so conjoined, i.e., components that are conjunctively present in some cases and disjunctively present in other cases. Multiple components listed with “and/or” should be construed in the same fashion, i.e., “one or more” of the components so conjoined. Other components may optionally be present other than the components specifically identified by the “and/or” clause, whether related or unrelated to those components specifically identified. Thus, as a non-limiting example, a reference to “A and/or B”, when used in conjunction with open-ended language such as “comprising” can refer, in one embodiment, to A only (optionally including components other than B); in another embodiment, to B only (optionally including components other than A); in yet another embodiment, to both A and B (optionally including other components); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of components, and, optionally, additional unlisted items. Only terms clearly indicated to the contrary, such as “only one of” or “exactly one of,” or, when used in the claims, “consisting of,” will refer to the inclusion of exactly one component of a number or list of components. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more components, should be understood to mean at least one component selected from any one or more of the components in the list of components, but not necessarily including at least one of each and every component specifically listed within the list of components and not excluding any combinations of components in the list of components. This definition also allows that components may optionally be present other than the components specifically identified within the list of components to which the phrase “at least one” refers, whether related or unrelated to those components specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including components other than B); in another embodiment, to at least one, optionally including more than one, B, with no A present (and optionally including components other than A); in yet another embodiment, to at least one, optionally including more than one, A, and at least one, optionally including more than one, B (and optionally including other components); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of detecting a microwave photon, the method comprising:
coupling the microwave photon into a microwave cavity;
transducing the microwave photon into a microwave phonon in a phononic cavity;
absorbing the microwave phonon by a color center, absorption of the microwave phonon by the color center causing an electron spin of the color center to change state; and
reading out the state of the electron spin, the state of the electron spin indicating a presence or absence of the microwave photon in the microwave cavity.

2. The method of claim 1, wherein coupling the microwave photon into the microwave cavity comprises receiving the microwave photon with an antenna coupled to the microwave cavity.

3. The method of claim 1, wherein transducing the microwave photon into the microwave phonon in the phononic cavity comprises applying a current pulse to a piezoelectric transducer coupling the microwave cavity to the phononic cavity.

4. The method of claim 1, wherein reading out the state of the electron spin comprises performing a single-shot readout of the state of the electron spin.

5. The method of claim 4, wherein performing the single-shot readout of the state of the electron spin comprises illuminating the color center with an optical pulse and detecting light emitted by the color center in response to the optical pulse.

6. The method of claim 1, wherein the color center is in an ensemble of color centers coupled to the phononic cavity and reading out the state of the electron spin comprises performing a dispersive readout of states of the electron spins of ensemble of color centers.

7. The method of claim 6, wherein performing the dispersive readout of states of the electron spins of ensemble of color centers comprises making a homodyne measurement of microwave radiation reflected and/or transmitted by the phononic cavity.

8. The method of claim 1, wherein detecting the presence of the microwave photon is at a detection efficiency of 0.91-0.94 with a mutual information of 0.57 ln(2)-0.67 ln(2).

9. A system for detecting a microwave photon, the system comprising:
a microwave cavity to receive the microwave photon;
a piezoelectric transducer, operably coupled to the microwave cavity, to transduce the microwave photon into a microwave phonon;
a phononic cavity, operably coupled to the piezoelectric transducer, to receive the microwave phonon;
a color center, operably coupled to the phononic cavity, to absorb the microwave phonon, absorption of the microwave phonon by the color center causing an electron spin of the color center to change state; and
a detector, in electromagnetic communication with the color center, to read out the state of the electron spin, the state of the electron spin indicating a presence or absence of the microwave photon in the microwave cavity.

10. The system of claim 9, wherein the phononic cavity is an optomechanical cavity supporting at least one phononic mode and at least one optical mode.

11. The system of claim 10, wherein the optomechanical cavity comprises diamond patterned with holes and doped with the color center.

12. The system of claim 9, further comprising:
an antenna, operably coupled to the microwave cavity, to couple the microwave photon into the microwave cavity.

13. The system of claim 9, further comprising:
a current source, operably coupled to the piezoelectric transducer, to tune a coupling strength of the microwave cavity to the phononic cavity via the piezoelectric transducer.

14. The system of claim 9, further comprising:
a laser, in optical communication with the color center, to illuminate the color center with a laser pulse,
wherein the detector is a photodetector configured to detect light emitted by the color center in response to the laser pulse, the light indicating the state of the electron spin.

15. The system of claim 9, wherein the color center is in an ensemble of color centers coupled to the phononic cavity.

16. The system of claim 15, further comprising:
a microwave source, in electromagnetic communication with the phononic cavity, to probe a resonance of the phononic cavity,
wherein the detector is configured to make a homodyne measurement of the resonance of the phononic cavity, the resonance of the phononic cavity indicating the state of the electron spin.

17. The system of claim 9, wherein the system is configured to detect a presence of the microwave photon with a detection efficiency of 0.91-0.94 and a mutual information of 0.57 ln(2)-0.67 ln(2).

18. A method of detecting a single microwave photon, the method comprising:
initializing a spin state of a color center coupled to a phononic cavity;
mapping the single microwave photon to the spin state of the color center via the phononic cavity; and
reading out the spin state of the color center, the spin state of the color center indicating detection of the single microwave photon.

19. The method of claim 18, wherein mapping the single microwave photon to the spin state of the color center comprises one of quantum state transduction, adiabatic mapping, or ensemble mapping.

20. The method of claim 18, wherein reading out the spin state of the color center comprises one of a single-shot readout of the spin state of the color center or dispersive readout of spin states of an ensemble of color centers comprising the color center.
